(19) United States
(12) Patent Application Publication
(10) Pub. No.: US 2020/0123648 A1
(43) Pub. Date: Apr. 23, 2020

(54) VACUUM SPUTTERING APPARATUS AND ITS VACUUM ATMOSPHERE EXCHANGE DEVICE

(71) Applicant: Shenzhen China Star Optoelectronics Technology Co., Ltd., Shenzhen, Guangdong (CN)

(72) Inventor: Qiuping HUANG, Shenzhen, Guangdong (CN)

(21) Appl. No.: 15/747,596

(22) PCT Filed: Jan. 4, 2018
(86) PCT No.: PCT/CN2018/071266

§ 371 Date: Jan. 25, 2018

(30) Foreign Application Priority Data
Dec. 27, 2017 (CN) 201711444816.3

(51) Int. Cl. C23C 14/54; H01J 37/34; C23C 14/34; C23C 14/56

(52) U.S. Cl. CPC C23C 14/541; H01J 37/3488; H01J 2237/204; C23C 14/56; H01J 2237/002; C23C 14/34

(57) ABSTRACT

A vacuum atmosphere exchange device used in a vacuum sputtering apparatus is provided. The vacuum atmosphere exchange device has a substrate transferring track. The vacuum atmosphere exchange device has a cooling device disposed along a transferring path of the substrate transferring track to rapidly cool down a film formation substrate on the substrate transferring track. A vacuum sputtering apparatus is also provided. By using the vacuum sputtering apparatus and the vacuum atmosphere exchange device thereof, the substrate after the deposition process can be rapidly cooled down such that the problem of film quality caused by high temperature and temperature non-uniformity can be resolved.

### RELATED APPLICATIONS

The present application is a National Phase of International Application Number PCT/CN2018/071266, filed Jan. 4, 2018, and claims the priority of China Application No. CN 201711444816.3, filed Dec. 27, 2017.

### FIELD OF THE DISCLOSURE

The present invention is related to the technical field of display panel manufacturing technology, and more particularly is related to a vacuum sputtering apparatus and a vacuum atmosphere exchange device thereof.

### BACKGROUND

Among the technologies nowadays, liquid crystal displays with the characteristics of low radiation, low power consumption, small size, and etc., have become the main trend of display devices and have been widely applied to the products such as cell phones, notebooks, tablets, TVs, and etc. Attending with the increasing panel size and demand of high pixel resolution, more and more production lines are equipped with large vacuum sputtering apparatuses with the features of large size, high power, and etc. to meet the demand of film formation of a larger area. On the other hand, in order to reduce resistance of conductive lines, the thickness of the film formed by sputtering should be increased, which may cause a rapid increase of temperature of the metal film.

For example, when depositing a copper film by using the conventional vacuum sputtering apparatus, based on the detected temperature curve, as the thickness of the copper film increases to 800 nm, the temperature of the substrate would reach a maximum of 190° C. The increase of substrate temperature would cause various problems such as oxidation of the coated film and non-uniformity caused by temperature, which may further influence the film quality and lower down the function of the apparatus.

### SUMMARY

The technical issue of the present invention is to provide a vacuum sputtering apparatus and a vacuum atmosphere exchange device thereof, which is capable to rapidly cool down the substrate after the deposition process, such that the problem of film quality caused by high temperature and temperature non-uniformity can be resolved.

In order to resolve the aforementioned technical problems, a vacuum atmosphere exchange device used in a vacuum sputtering apparatus is provided in an embodiment of the present invention. The vacuum atmosphere exchange device has a substrate transferring track. The vacuum atmosphere exchange device has a cooling device disposed along a transferring path of the substrate transferring track to rapidly cool down a film formation substrate on the substrate transferring track.

In an embodiment, the cooling device is disposed in a middle of the substrate transferring track and/or between the substrate transferring track and an inner wall of a chamber of the vacuum atmosphere exchange device.

In an embodiment, the cooling device is deposed around the substrate transferring track.

In an embodiment, the cooling device has a closed pipeline for circulating coolant, and the closed pipeline has an inlet and an outlet at two ends thereof.

In an embodiment, the cooling device is a blocky structure, which is a single block or composed of multiple blocks jointed together.

In an embodiment, the cooling device is coated with a black coating layer.

In an embodiment, the black coating layer is a carbon nanotube coating layer with infrared absorption capability or an inorganic semiconductor coating layer with infrared absorption capability.

In an embodiment, the cooling device has protrusions uniformly distributed on a surface thereof, and the protrusion is coated with a black coating layer.

In an embodiment, the black coating layer is a carbon nanotube coating layer with infrared absorption capability or an inorganic semiconductor coating layer with infrared absorption capability.

In order to resolve the aforementioned technical problems, a vacuum sputtering apparatus is also provided in the present invention. The vacuum sputtering apparatus comprises a substrate-advance chamber, a vacuum atmosphere exchange device connected to the substrate-advance chamber, a heating chamber connected to the vacuum atmosphere exchange device, and at least one film formation chamber connected to the heating chamber. The vacuum atmosphere exchange device has a substrate transferring track. The vacuum atmosphere exchange device has a cooling device disposed along a transferring path of the substrate transferring track to rapidly cool down a film formation substrate on the substrate transferring track. The cooling device is a blocky structure, which is a single block or composed of multiple blocks jointed together.

In an embodiment, the cooling device is disposed in a middle of the substrate transferring track and/or between the substrate transferring track and an inner wall of a chamber of the vacuum atmosphere exchange device, the cooling device has a closed pipeline therein for circulating coolant, and the closed pipeline has an inlet and an outlet at two ends thereof.

In an embodiment, the cooling device is deposed around the substrate transferring track, the cooling device has a closed pipeline therein for circulating coolant, and the closed pipeline has an inlet and an outlet at two ends thereof.

In an embodiment, the cooling device is coated with a black coating layer.

In an embodiment, the cooling device has protrusions uniformly distributed on a surface thereof, and the protrusion is coated with a black coating layer.

In an embodiment, the black coating layer is a carbon nanotube coating layer with infrared absorption capability or an inorganic semiconductor coating layer with infrared absorption capability.

The vacuum sputtering apparatus and the vacuum atmosphere exchange device thereof provided in the present invention have the following advantages. Because the vacuum atmosphere exchange device has a main body with a substrate transferring track disposed therein and a cooling device disposed along a transferring path of the substrate transferring track to rapidly cool down the film formation substrate on the substrate transferring track, the problem of film quality caused by high temperature and temperature non-uniformity can be resolved.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts.

FIG. 1 is a structural schematic view of a vacuum sputtering apparatus provided in accordance with an embodiment of the present invention.

FIG. 2 is a structural schematic view of a vacuum atmosphere exchange device used in a vacuum sputtering apparatus in accordance with a first embodiment of the present invention.

FIG. 3 is a structural schematic view of a vacuum atmosphere exchange device used in a vacuum sputtering apparatus in accordance with a second embodiment of the present invention.

FIG. 4 is a structural top view of a vacuum atmosphere exchange device used in a vacuum sputtering apparatus in accordance with a third embodiment of the present invention.

FIG. 5 is a structural side view of a vacuum atmosphere exchange device used in a vacuum sputtering apparatus in accordance with the third embodiment of the present invention.

### DETAILED DESCRIPTION OF PREFERRED EMBODIMENTS

The present disclosure is described in detail below with references to the accompanying drawings and specific embodiments. Apparently, the embodiments in the description below are merely some embodiments of the present invention, the embodiments obtained by a person skilled in the art without creative efforts should be regarded as within the scope of the present invention.

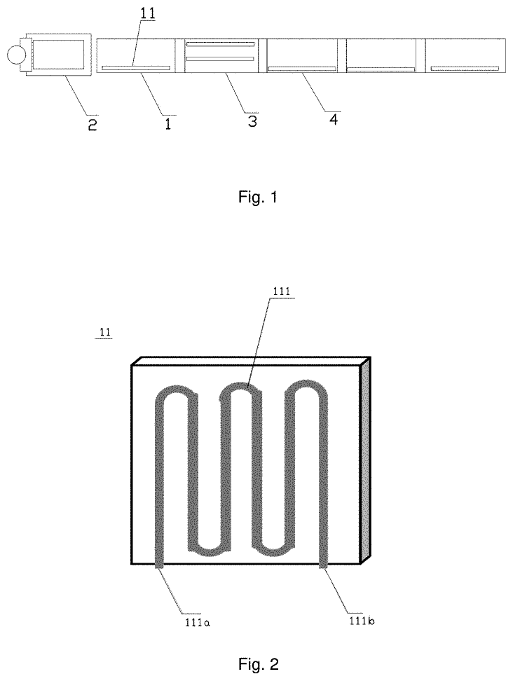

FIG. 1 is a structural schematic view of a vacuum sputtering apparatus provided in accordance with an embodiment of the present invention.

The vacuum sputtering apparatus in the present embodiment includes a substrate advance chamber 2, a vacuum atmosphere exchange device 1 connected to the substrate advance chamber 2, a heating chamber 3 connected to the vacuum atmosphere exchange device 1, and at least one film formation chamber 4 connected to the heating chamber 3.

In the vacuum sputtering apparatus of the present embodiment, the substrate advance chamber 2, the vacuum atmosphere exchange device 1, the heating chamber 3, and the film formation chamber 4 have the transferring tracks disposed therein for transferring the substrate. The transferring track can be an integrated track penetrating and connecting the aforementioned chambers, and also can be multiple fracks disposed in each of the chambers for transferring the substrate respectively. These tracks may be designed to transfer the substrate sequentially.

During the process, when the substrate in placed on a substrate carrier in the substrate advance chamber 2 (through the corresponding transferring track) prepared to be transferred to the vacuum atmosphere exchange device 1, the vacuum breaking mechanism of the vacuum atmosphere exchange device 1 would be started to draw the air from the atmosphere into the vacuum atmosphere exchange device 1 through the pipeline. As the pressure reaches the atmosphere, the door between the substrate advance chamber 2 and the vacuum atmosphere exchange device 1 would be opened, and the substrate would be transferred to the substrate transferring track in the vacuum atmosphere exchange device 1. Then, the door of the vacuum atmosphere exchange device 1 would be closed, and the air pump of the vacuum atmosphere exchange device 1 is started to remove the air in the vacuum atmosphere exchange device 1. After reaching the predetermined pressure value, the door to the heating chamber 3 is opened, and the substrate carrier is transferred to the heating chamber 3 (through the corresponding transferring track) such that the substrate advance process is completed once.

After completing the film-forming process in the film formation chamber 4, the substrate is transferred from the heating chamber 3 to the vacuum atmosphere exchange device 1. At this time, the vacuum atmosphere exchange device 1 is in a vacuum condition, and then the vacuum breaking mechanism of the vacuum atmosphere exchange device 1 would be started to draw the air into the vacuum atmosphere exchange device 1 through the pipeline. As the pressure reaches the atmosphere, the door between the vacuum atmosphere exchange device 1 and the substrate advance chamber 2 would be opened, and the substrate carrier would transfer the substrate to the substrate advance chamber 2. The aforementioned processes are repeated to implement the switching between the vacuum condition and the atmosphere condition.

FIG. 2 is a structural schematic view of a vacuum atmosphere exchange device used in a vacuum sputtering apparatus in accordance with a first embodiment of the present invention.

The vacuum atmosphere exchange device 1 used in the vacuum sputtering apparatus has a substrate transferring track (not shown). The substrate transferring track may be used to catch up the corresponding transferring track of the substrate carrier in the substrate advance chamber 2. The vacuum atmosphere exchange device 1 has a cooling device 11 disposed along a transferring path of the substrate transferring track to rapidly cool down the film formation substrate on the substrate transferring track.

Concretely speaking, the cooling device 11 may be disposed in a middle of the substrate transferring track in the vacuum atmosphere exchange device 1, such as the position under the substrate carried by the substrate carrier, such that the cooling device 11 is capable to rapidly cool down a single side of the substrate. Moreover, the cooling device 11 may be disposed on an inner wall of the vacuum atmosphere exchange device 1 or between the substrate transferring track and the inner wall of a chamber of the vacuum atmosphere exchange device, so as to rapidly cool down both sides of the substrate.

Preferably, the relative position between the cooling device 11 and the substrate carried by the substrate carrier is: to have the cooling device 11 kept within 20 mm from the substrate transferring path, to keep a lowest safe transferring path and a closest distance, i.e. the relative position that the substrate can be transferred safely without touching the cooling device, meanwhile, a minimum gap is kept to implement best cooling effect and temperature uniformity.

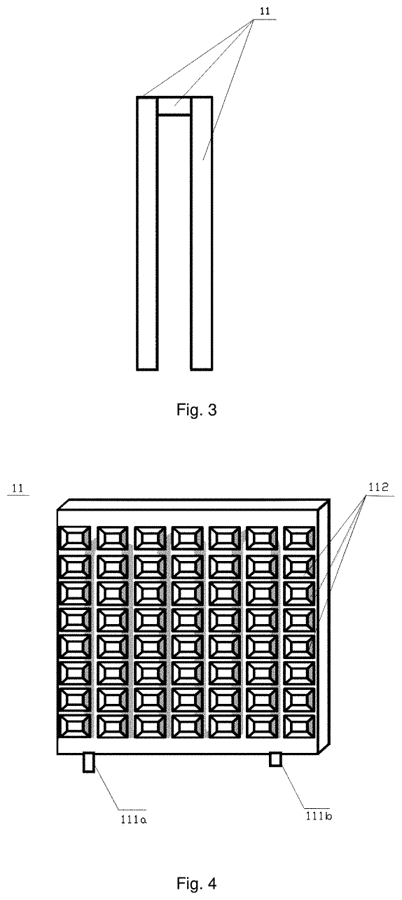

Furthermore, the cooling device 11 is a blocky structure, which is a single block or composed of multiple blocks jointed together. For example, the embodiment shown in FIG. 2 is a single block, and the embodiment shown in FIG. 3 is a door-shaped structure with multiple blocks jointed together.

Furthermore, the cooling device 11 has a closed pipeline 111 for circulating coolant. The closed pipeline 111 has an inlet 111a and an outlet 111b at two ends thereof. During the cooling process, the inlet 111a and the outlet 111b for injecting and removing the coolant are connected to the external pipelines outside the vacuum atmosphere exchange device 1. The coolant can be a conventional coolant or water. In the other embodiment of the present invention, the cooling device 11 may have multiple closed pipelines to enhance cooling effect.

Furthermore, the cooling device 11 is coated with a black coating layer. The black coating layer is a carbon nanotube coating layer with infrared absorption capability or an inorganic semiconductor coating layer with infrared absorption capability, so as to increase the absorption coefficient of the surface of the cooling device 11 to enhance absorption rate of radiation.

FIG. 3 is a structural schematic view of a vacuum atmosphere exchange device used in a vacuum sputtering apparatus in accordance with a second embodiment of the present invention.

The difference between the vacuum atmosphere exchange device used in the vacuum sputtering apparatus of the present embodiment and the first embodiment is that: the cooling device 11 in the present embodiment is a door-shaped structure with multiple blocks jointed together. That is, the cooling device 11 is deposed around the substrate transferring track, and the substrate carried by the substrate carrier is transferred in the middle of the cooling device 11. The surrounding cooling arrangement may enhance the cooling effect maximally.

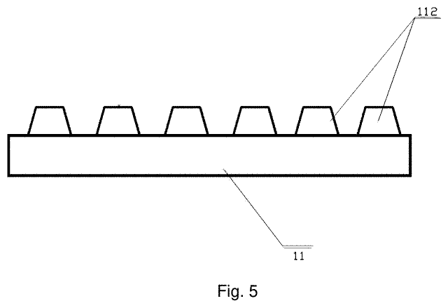

FIG. 4 and FIG. 5 are schematic views showing a vacuum atmosphere exchange device used in a vacuum sputtering apparatus in accordance with a third embodiment of the present invention.

The difference between the vacuum atmosphere exchange device used in the vacuum sputtering apparatus of the present embodiment and the first embodiment is that: the cooling device 11 has protrusions 112 uniformly distributed on a surface thereof. The protrusion 112 is coated with a black coating layer. The black coating layer is a carbon nanotube coating layer with infrared absorption capability or an inorganic semiconductor coating layer with infrared absorption capability.

Concretely speaking, the function of the protrusion 112 uniformly distributed on the surface of the cooling device 11 is that: the protrusions 112 are capable to increase the surface area of thermal radiation, and the black coating layer coated on the protrusion 112 is capable to increase the absorption coefficient of the surface of the cooling device 11 so as to enhance absorption rate of radiation.

The vacuum sputtering apparatus and the vacuum atmosphere exchange device thereof provided in the present invention have the following advantages. Because the vacuum atmosphere exchange device has a main body with a substrate transferring track disposed therein and a cooling device disposed along a transferring path of the substrate transferring track to rapidly cool down the film formation substrate on the substrate transferring track, the problem of film quality caused by high temperature and temperature non-uniformity can be resolved.

What is claimed is:

1. A vacuum atmosphere exchange device, used in a vacuum sputtering apparatus, wherein the vacuum atmosphere exchange device has a substrate transferring track, wherein the vacuum atmosphere exchange device has a cooling device disposed along a transferring path of the substrate transferring track to rapidly cool down a film formation substrate on the substrate transferring track.

2. The vacuum atmosphere exchange device of claim 1, wherein the cooling device is disposed in a middle of the substrate transferring track and/or between the substrate transferring track and an inner wall of a chamber of the vacuum atmosphere exchange device.

3. The vacuum atmosphere exchange device of claim 1, wherein the cooling device is deposed around the substrate transferring track.

4. The vacuum atmosphere exchange device of claim 2, wherein the cooling device has a closed pipeline for circulating coolant, and the closed pipeline has an inlet and an outlet at two ends thereof.

5. The vacuum atmosphere exchange device of claim 3, wherein the cooling device has a closed pipeline therein for circulating coolant, and the closed pipeline has an inlet and an outlet at two ends thereof.

6. The vacuum atmosphere exchange device of claim 1, wherein the cooling device is a blocky structure, which is a single block or composed of multiple blocks jointed together.

7. The vacuum atmosphere exchange device of claim 1, wherein the cooling device is coated with a black coating layer.

8. The vacuum atmosphere exchange device of claim 7, wherein the black coating layer is a carbon nanotube coating layer with infrared absorption capability or an inorganic semiconductor coating layer with infrared absorption capability.

9. The vacuum atmosphere exchange device of claim 1, wherein the cooling device has protrusions uniformly distributed on a surface thereof, and the protrusion is coated with a black coating layer.

10. The vacuum atmosphere exchange device of claim 9, wherein the black coating layer is a carbon nanotube coating layer with infrared absorption capability or an inorganic semiconductor coating layer with infrared absorption capability.

11. A vacuum sputtering apparatus, comprising a substrate-advance chamber, a vacuum atmosphere exchange device connected to the substrate-advance chamber, a heating chamber connected to the vacuum atmosphere exchange device, and at least one film formation chamber connected to the heating chamber, wherein the vacuum atmosphere exchange device has a substrate transferring track, wherein the vacuum atmosphere exchange device has a cooling device disposed along a transferring path of the substrate transferring track to rapidly cool down a film formation substrate on the substrate transferring track, wherein the cooling device is a blocky structure, which is a single block or composed of multiple blocks jointed together.

12. The vacuum sputtering apparatus of claim 11, wherein the cooling device is disposed in a middle of the substrate transferring track and/or between the substrate transferring track and an inner wall of a chamber of the vacuum atmosphere exchange device, the cooling device has a closed pipeline therein for circulating coolant, and the closed pipeline has an inlet and an outlet at two ends thereof.

13. The vacuum sputtering apparatus of claim 11, wherein the cooling device is deposed around the substrate transferring track, the cooling device has a closed pipeline therein for circulating coolant, and the closed pipeline has an inlet and an outlet at two ends thereof.

14. The vacuum sputtering apparatus of claim 11, wherein the cooling device is coated with a black coating layer.

15. The vacuum sputtering apparatus of claim 14, wherein the black coating layer is a carbon nanotube coating layer with infrared absorption capability or an inorganic semiconductor coating layer with infrared absorption capability.

16. The vacuum sputtering apparatus of claim 11, wherein the cooling device has protrusions uniformly distributed on a surface thereof, and the protrusion is coated with a black coating layer.

17. The vacuum sputtering apparatus of claim 16, wherein the black coating layer is a carbon nanotube coating layer with infrared absorption capability or an inorganic semiconductor coating layer with infrared absorption capability.
